(19) United States
(12) Patent Application Publication
(10) Pub. No.: US 2025/0158596 A1
(43) Pub. Date: May 15, 2025

(54) PHASE AMPLITUDE CONTROLLER

(71) Applicant: Qorvo US, Inc., Greensboro, NC (US)

(72) Inventors: Joel Johnson, Wylie, TX (US); Nikolaus Klemmer, Dallas, TX (US)

(21) Appl. No.: 18/904,321

(22) Filed: Oct. 2, 2024

Related U.S. Application Data
(60) Provisional application No. 63/548,035, filed on Nov. 10, 2023.

(51) Int. Cl. H03H 11/16; H04B 7/06; H04W 16/28; H04W 88/08

(52) U.S. Cl. CPC H03H 11/16; H04B 7/0617; H04W 16/28; H04W 88/08

(57) ABSTRACT

Phase amplitude controllers are disclosed. In one aspect, a phase amplitude controller may be formed by splitting a signal into two paths. Each path uses an independently controlled phase adjusting circuit to adjust a phase of the signal on that path. The signals are then recombined. By selecting an appropriate total phase adjustment and a relative phase adjustment, not just the phase but also the amplitude of the resulting combined signal may be controlled. In this fashion, a phase amplitude controller may be formed with fewer parts, thereby taking up less space, weighing less, and being more amenable to use in a retrofit antenna array. Additionally, the reduction in parts may lower the cost, meaning that antenna arrays with many duplicated phase amplitude controllers may be cheaper.

### PRIORITY APPLICATION

This application claims the benefit of U.S. Provisional Patent Application Ser. No. 63/548,035, filed on Nov. 10, 2023, entitled “PHASE AMPLITUDE CONTROLLER,” the disclosure of which is hereby incorporated herein by reference in its entirety.

### BACKGROUND

### I. Field of the Disclosure

The technology of the disclosure relates generally to a technique to improve a phase amplitude controller, such as may be used with an antenna array for a transceiver in a wireless communication system.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to increase bandwidth for data transmission to and from the user equipment or other wireless communication devices. This pressure has resulted in the evolution of wireless protocols and a current trend to use higher frequency signals that are steered using an array of antennas. As the number of antennas in an array increases, the number of supporting circuits also increases. In many cases, updates are installed on pre-existing hardware, which has limited space available. Accordingly, there is pressure to decrease the amount of space the supporting circuits consume so that the proliferating supporting circuits may still fit within the limited space. Such pressures provide room for innovation.

### SUMMARY

Aspects disclosed in the detailed description include phase amplitude controllers, which may be used in base station transceivers in a wireless communication system. In particular, a phase amplitude controller may be formed by splitting a signal into two paths. Each path uses an independently controlled phase adjusting circuit to adjust a phase of the signal on that path. The signals are then recombined. By selecting an appropriate total phase adjustment and a relative phase adjustment, not just the phase but also the amplitude of the resulting combined signal may be controlled. In this fashion, a phase amplitude controller may be formed with fewer parts, thereby taking up less space, weighing less, and being more amenable to use in a retrofit antenna array. Additionally, the reduction in parts may lower the cost, meaning that antenna arrays with many duplicated phase amplitude controllers may be cheaper.

In this regard, in one aspect, a transceiver is disclosed. The transceiver includes a phase amplitude controller (PAC) comprising a power splitter configured to provide two signals and a first variable phase shifter coupled to the power splitter and configured to phase shift a first signal of the two signals, wherein the first variable phase shifter is configured to provide a selected phase shift between zero and one hundred eighty degrees. The transceiver also includes a second variable phase shifter coupled to the power splitter and configured to phase shift a second signal of the two signals and a power combiner coupled to the first variable phase shifter and the second variable phase shifter and configured to combine even modes of the first signal and the second signal while discarding odd modes of the first signal and the second signal such that phase and amplitude are adjusted based on phase shifts provided by the first variable phase shifter and the second variable phase shifter.

In another aspect, an antenna panel configured to be coupled to a tower to provide wireless communication service to user equipment is disclosed. The antenna panel includes a housing and a plurality of antenna elements on a front face of the housing. The antenna panel also includes a corresponding plurality of transceivers for respective ones of the plurality of antenna elements, wherein each of the corresponding plurality of transceivers comprises a PAC, which includes a power splitter configured to provide two signals and a first variable phase shifter coupled to the power splitter and configured to phase shift a first signal of the two signals. The antenna panel further includes a second variable phase shifter coupled to the power splitter and configured to phase shift a second signal of the two signals and a power combiner coupled to the first variable phase shifter and the second variable phase shifter and configured to combine even modes of the first signal and the second signal while discarding odd modes of the first signal and the second signal such that phase and amplitude are adjusted based on phase shifts provided by the first variable phase shifter and the second variable phase shifter.

In another aspect, a method of adjusting the phase and amplitude of a signal is disclosed. The method includes splitting a signal using a power splitter into a first signal and a second signal and using a first variable phase shifter to adjust a first phase of the first signal. The method also includes using a second variable phase shifter to adjust a second phase of the second signal and combining the first signal and the second signal with a power combiner such that even modes of the first signal and the second signal are constructively summed while discarding odd modes of the first signal and the second signal such that phase and amplitude are adjusted based on phase shifts provided by the first variable phase shifter and the second variable phase shifter.

### BRIEF DESCRIPTION OF THE DRAWINGS

FIG. 1A is a stylized diagram of an exemplary tower with a plurality of antenna arrays mounted thereon;

FIG. 1B is a top-down view of the tower of FIG. 1A, showing how a cell may be divided amongst the antenna arrays;

FIG. 2A is a front elevational view of an antenna array that may be used on the tower of FIG. 1A;

FIG. 2B is a stylized diagram of a beam formed by the antenna array of FIG. 2A using beam-forming techniques;

FIG. 2C is an example of phase shifts applied to different antennas in the antenna array to form beams;

FIG. 3 is a block diagram of a transceiver assembly having transmitters and receivers with associated antenna elements that may be used to form an antenna array;

FIG. 4 is a block diagram of a conventional phase amplitude controller (PAC) that may duplicated across each transmitter in a conventional transceiver assembly;

FIG. 5 is a stylized diagram of a PAC according to an exemplary aspect of the present disclosure;

FIG. 6A is a graph of phase versus attenuation achieved by the PAC of FIG. 5, highlighting an area of poor attenuation resolution;

FIG. 6B is a graph of phase versus attenuation achieved by the PAC of FIG. 5 with additional phase resolution bits;

FIG. 7 is a stylized diagram of a PAC according to another exemplary aspect of the present disclosure;

FIG. 8 is a graph of phase versus attenuation achieved by the PAC of FIG. 7;

FIGS. 9A-9C are circuit diagrams of exemplary phase shifting circuits that may be used in the PAC of FIG. 5 or FIG. 7;

FIG. 10 is a flowchart illustrating a method for selecting a reasonable amount of data points for use in a look-up table; and

FIG. 11 is a stylized representation of the look-up table derived by the process of FIG. 10.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure defines “transceiver.” Current industry literature uses the term “transceiver” in two primary ways. In a first meaning, the term refers broadly to a plurality of circuits that send and receive signals. In this broader context, exemplary circuits may include a baseband processor, an up/down conversion circuit, filters, amplifiers, couplers, and the like coupled to one or more antennas. In contrast, in the second meaning, some authors in the industry literature refer specifically to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Aspects disclosed in the detailed description include phase amplitude controllers such as may be used in base station transceivers in a wireless communication system. In particular, a phase amplitude controller may be formed by splitting a signal into two paths. Each path uses an independently controlled phase adjusting circuit to adjust a phase of the signal on that path. The signals are then recombined. By selecting an appropriate total phase adjustment and a relative phase adjustment, not just the phase but also the amplitude of the resulting combined signal may be controlled. In this fashion, a phase amplitude controller may be formed with fewer parts, thereby taking up less space, weighing less, and being more amenable to use in a retrofit antenna array. Additionally, the reduction in parts may lower the cost, meaning that antenna arrays with many duplicated phase amplitude controllers may be cheaper.

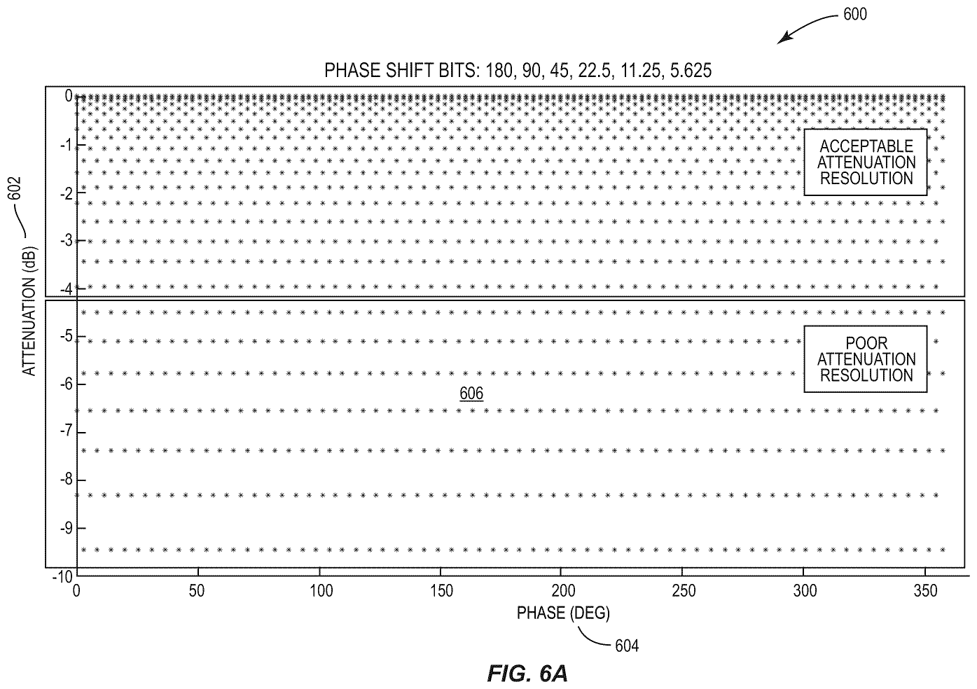

Before addressing exemplary aspects of the present disclosure, a discussion of parts of a wireless communication system is provided for context. A discussion of exemplary aspects begins below with reference to FIG. 5.

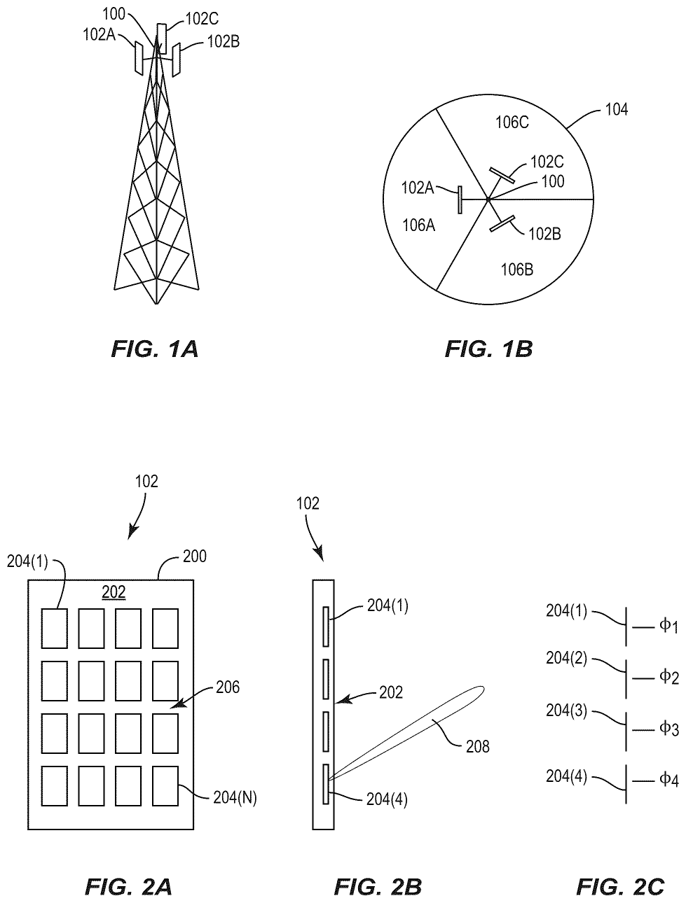

In this regard, FIGS. 1A and 1B are a stylized representation of a cellular tower 100 with antenna panels 102A-102C positioned thereon. Typically, there are three antenna panels 102A-102C, effectively dividing a cell 104 into one hundred twenty degree (120°) arcs 106A-106C.

As the number of users and/or the amount of data users are sending and receiving through a wireless system increases, there is a need for increased bandwidth to accommodate this use. One of the easiest ways to accommodate this use is to increase a number of cells 104. However, one of the most expensive parts of a wireless system is the approval and installation of a cellular tower 100 (e.g., acquiring easements, regulatory approval, construction, etc.) Accordingly, there is pressure to provide alternative ways to increase the bandwidth available. Changing frequencies used, and specifically increasing a frequency over which information bearing signals are transmitted, provides such an alternative way to increase bandwidth. Indeed, the evolution from 3G to 4G to 5G has seen increases in frequencies used. 6G proposals further increase the frequency range to frequency range 3 (FR3) and specifically to two contemplated bands (e.g., 6.4-7.1 GHz and 12.7-13.1 GHZ). To handle the higher frequencies of 5G and 6G as well as reduce interference between users, antenna arrays and beamforming are contemplated. Such an approach creates a more focused signal path between the tower 100 and an end user.

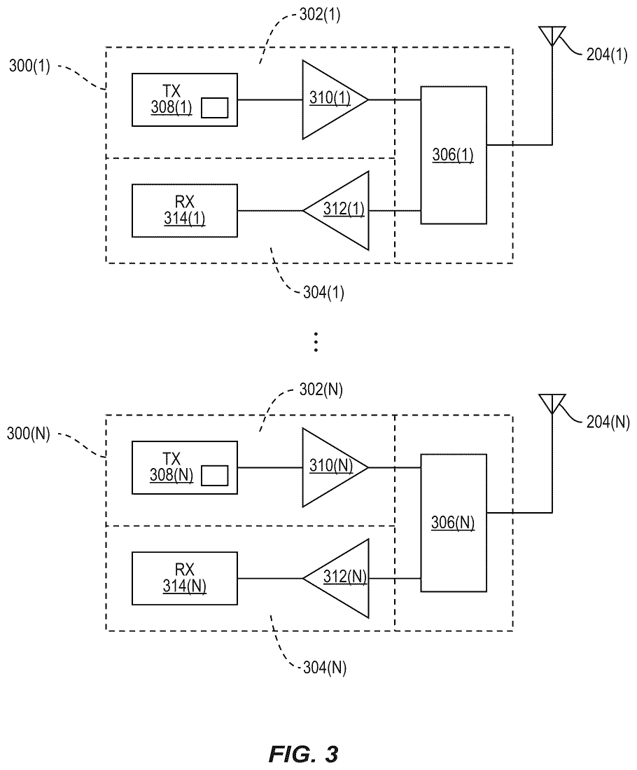

As noted, to provide beamforming, an antenna array in an antenna panel is used. A generic antenna panel 102 is illustrated in FIGS. 2A-2B, with some pieces also illustrated in 2C. An antenna panel 102 may have a housing 200 with a fixed size and weight tolerance. On a front facing surface 202, a plurality of antenna elements 204(1)-204(N) may be positioned to form an antenna array 206. Beamforming techniques may be applied to the signals radiated by the antenna elements 204(1)-204(N) to form a beam 208 as shown in FIG. 2B. In particular, as shown in FIG. 2C, a respective phase shift Φ₁-Φ_{N} may be applied to the antenna elements 204(1)-204(N) (only 204(1)-204(4) and Φ₁-Φ₄ shown).

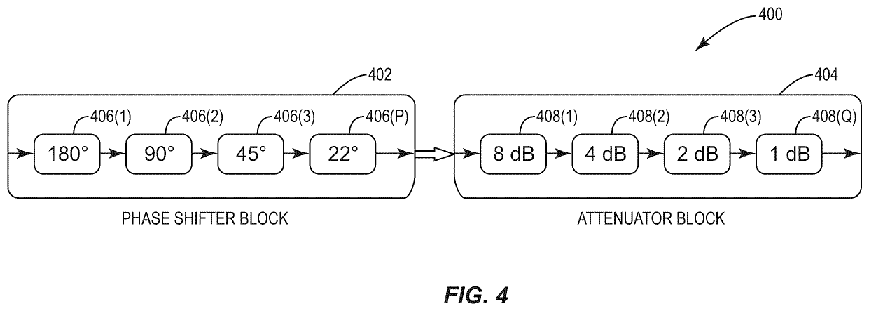

Each antenna element 204(1)-204(N) has an associated transceiver circuit 300(1)-300(N) better illustrated in FIG. 3. The transceiver circuits 300(1)-300(N) may have a respective transmit chain 302(1)-302(N) and a respective receive chain 304(1)-304(N) coupled by a switch or coupler 306(1)-306(N). Each transmit chain 302(1)-302(N) may include a transmit circuit 308(1)-308(N), which includes baseband and radio frequency processing circuitry, and a power amplifier stage 310(1)-310(N) to boost the signal to a desired level. Similarly, each receive chain 304(1)-304(N) may include a low noise amplifier (LNA) stage 312(1)-312(N) and a receive circuit 314(1)-314(N), which may downconvert an RF signal to baseband and provide additional processing. Note that there may be additional circuits, such as filters, power management integrated circuits (PMICs), bias circuits, or the like (none shown), without departing from the present disclosure.

In practice, each transceiver circuit 300(1)-300(N) is positioned within the housing 200. Thus, as the number N of antenna elements 204 increases, the number of transceiver circuits 300 also increases. Each additional transceiver circuit 300 increases spaced consumed in the housing 200 and adds weight thereto. Given the desire to reuse existing towers 100 and housings 200, there is increased pressure to find ways to reduce the size and/or weight of the components within the housing 200.

The advent of beamforming has actually added components to the transmit circuits 308(1)-308(N). Specifically, there may be a phase amplitude controller (PAC) present that adjusts the phase of a signal so that the signal will coherently add at a desired angle with other signals from the antenna array and adjusts the amplitude to control side lobes of a transmitted signal.

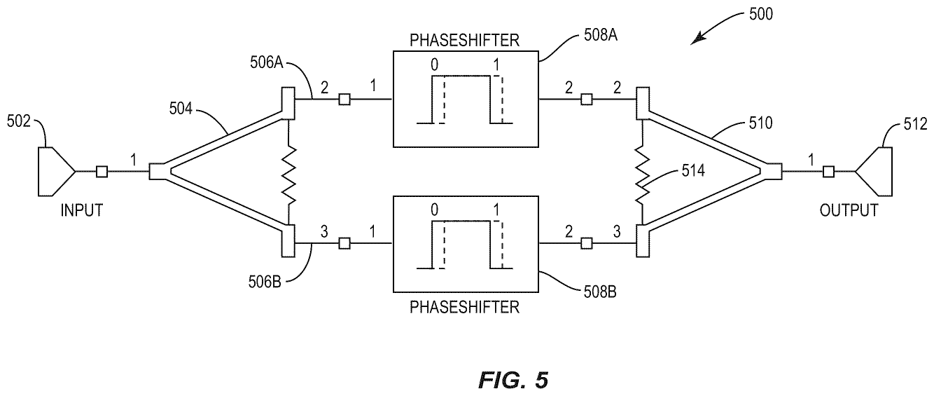

An exemplary PAC 400 is illustrated in FIG. 4. Specifically, the PAC 400 may include a phase shifter block 402 and an attenuator block 404. The phase shifter block 402 may include a plurality of circuits 406(1)-406(P) (as illustrated P=4), which correspond to bits of adjustment to the phase. The attenuator block 404 may likewise have a plurality of circuits 408(1)-408(Q) (as illustrated Q=4), which correspond to bits of adjustment for the amplitude.

Usually, the blocks 402 and 404 are independently designed, and may not have a precise impedance match. Such imprecise impedance matching may increase errors in transmission and/or create high insertion losses, particularly at FR3 frequencies. These structures may struggle at finer attenuations and phase shift steps. Such struggles lend themselves to increasing P or Q, which in turn adds circuitry, which in turn consumes more space, increases costs, and increases weight. Thus, there is room to provide a simpler, low cost, lighter, smaller solution.

Exemplary aspects of the present disclosure contemplate providing a power splitter to split a signal into two equal signals. The equal signals are subjected to independent phase shifts and recombined. By selecting appropriate relative phase shifts, both a final phase shift and amplitude may be adjusted.

An exemplary aspect of such a PAC is illustrated in FIG. 5, where a PAC 500 includes an input node 502 coupled to a power splitter 504. In an exemplary aspect, the power splitter 504 is a Wilkinson power splitter. The power splitter 504 has two output paths 506A, 506B, each of which is coupled to a respective phase shifter 508A, 508B. The phase shifters 508A, 508B may be binary weighted phase controllers and variable in that they are capable of providing a selected phase shift between zero and one hundred eighty degrees. That is, while at a given time, a single phase shift is applied by a given phase shifter 508A, 508B, the phase shift may be changed from moment to moment as needed or desired. The phase shifters 508A, 508B are coupled to a power combiner 510, which may also be based on a Wilkinson power combiner. The even modes of the two signals are added together, but the odd mode signal is dissipated at an isolation resistor 514 of the power combiner 510. The power combiner 510 may be coupled to an output node 512. By controlling the relative phase introduced by phase shifters 508A, 508B, the PAC 500 may provide a desired cancelation of a certain part of the signal presented at the input node 502 and that the remaining signal that exits at the output node 512 has a desired phase.

More completely the output signal may be expressed as:

$${V}_{o} = \frac{V}{2} [ 2 cos ( ω t + ϕ ) \times cos ( \frac{{Δ}_{ϕ}}{2} ) ]$$

Where the

$$[ cos ( \frac{{Δ}_{ϕ}}{2} ) ]$$

term is the attenuation factor. However, using only phase shifters is not a practical solution since attenuation depends on

$$[ cos ( \frac{{Δ}_{ϕ}}{2} ) ] 2 .$$

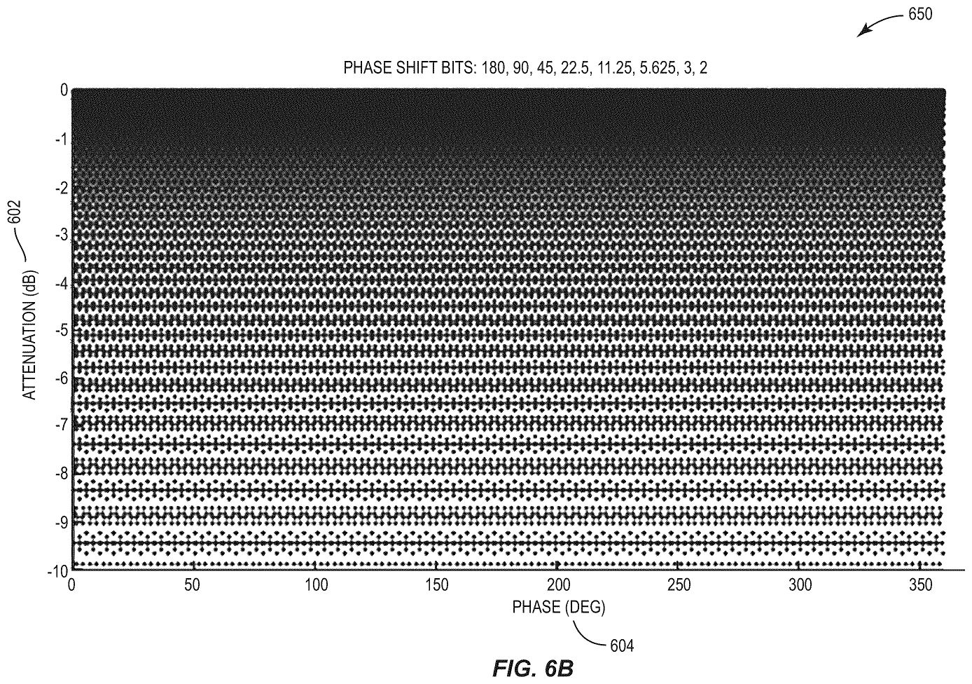

This means that a Ag for 0.5 dB of attenuation changes at different levels of attenuation. A graph 600 of attenuation (vertical axis 602) versus phase (horizontal axis 604) for a six-bit phase shifter shows the resolution that is readily achievable as illustrated in FIG. 6A. At attenuations greater than −4 dB, the resolution is generally poor (area 606) and for attenuation greater than −10 dB, the solution is impractical.

One solution is to add bits to the phase shifters. For example, adding two bits results in a graph 650 illustrated in FIG. 6B. While there is some degradation in the resolution at attenuations greater than −8 dB, in general, the resolution is satisfactory for most applications.

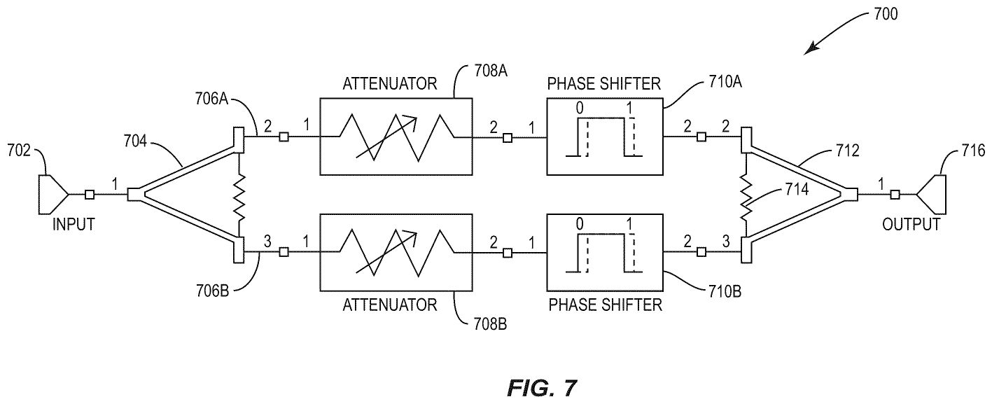

However, a more robust option is to add small coarse attenuator circuits as better seen in FIG. 7. Specifically, a PAC 700 may include an input node 702 configured to receive an input signal. The input node 702 is coupled to a power splitter 704, which may be a Wilkinson power splitter. The power splitter 704 has two output paths 706A, 706B, each of which is coupled to a respective adjustable or variable attenuator 708A, 708B. The variable attenuators 708A, 708B may have, for example, no more than three bits of adjustment available. The variable attenuators 708A, 708B are coupled to respective phase shifters 710A, 710B. The phase shifters 710A, 710B may be binary weighted phase controllers and may function identically to the phase shifters 508A, 508B. The phase shifters 710A, 710B are coupled to a power combiner 712, which may also be based on a Wilkinson power combiner. The even modes of the two signals are added together, but the odd mode signal is dissipated at an isolation resistor 714 of the power combiner 712. The power combiner 712 may be coupled to an output node 716. The addition of the coarse amplitude control bits in each path provides many more possible solutions and allows for more attenuation range.

For PAC 700, the output may be expressed:

$${V}_{o} = {{V}_{i} [ {( cos {Φ}_{1} + {A}_{c} sin {Φ}_{2} )}^{2} + {( sin {Φ}_{1} + {A}_{c} cos {Φ}_{2} )}^{2} ]}^{\frac{1}{2}} \times sin ( ω t - {tan}^{- 1} ( \frac{sin {Φ}_{1} + {A}_{c} cos {Φ}_{2}}{cos {Φ}_{1} + {A}_{c} sin {Φ}_{2}} ) )$$

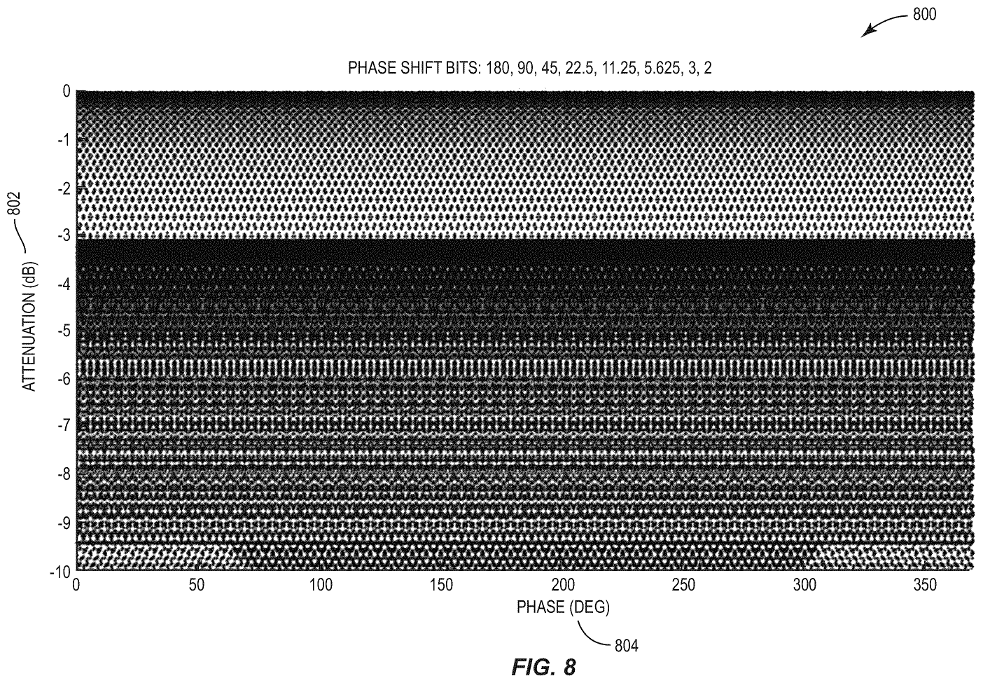

The resultant resolution is illustrated by graph 800 of FIG. 8, where vertical axis 802 and horizontal axis 804 correspond to axes 602, 604 respectively. As is readily apparent, the resolution is much greater.

Note that for either PAC 500 or PAC 700, the Wilkinson power combiners and dividers may be replaced with hybrid couplers or any other power splitter as needed or desired.

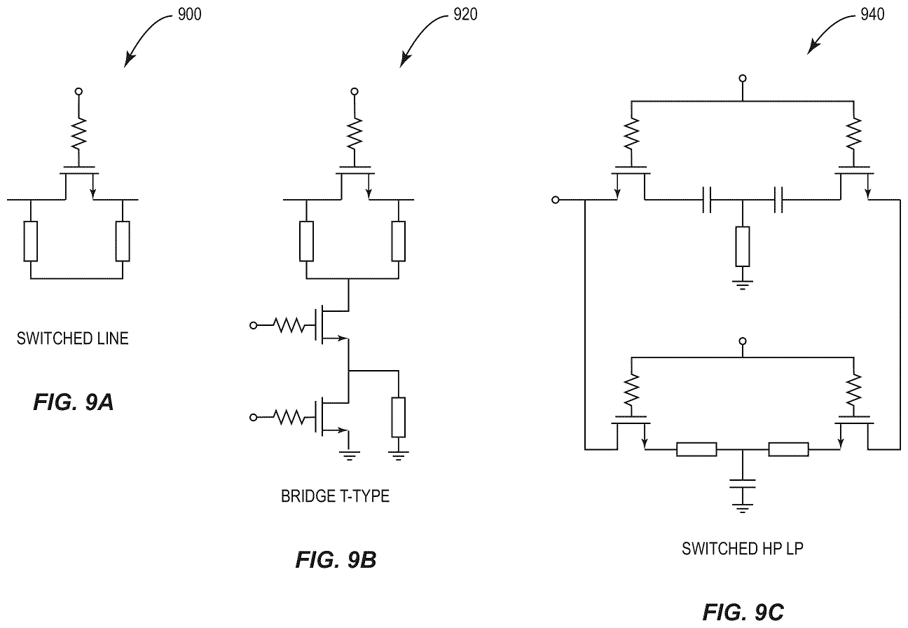

Note further that the phase shifters may be formed from a variety of circuits. FIGS. 9A-9C illustrate various exemplary circuits 900, 920, 940, respectively. For less significant bits, a switched line structure circuit 900 may be used. For moderately significant bits, a bridge T-type structure circuit 920 may be used. For the most significant bits, a switched high pass-low pass topology circuit 940 may be used. Still other structures are possible.

Once the structure is made (i.e., either PAC 500 or PAC 700), post-processing or testing yields a set of possible codes that provide a desired amplitude and phase control in the desired resolution. These codes can be tailored to minimize any error required by the system. Further, the codes may be tested across multiple frequencies in the frequency bands of interest and a “best fit” chosen. While the “best fit” may not be the optimal choice for any given frequency, amplitude, and phase, it may have the lowest common error.

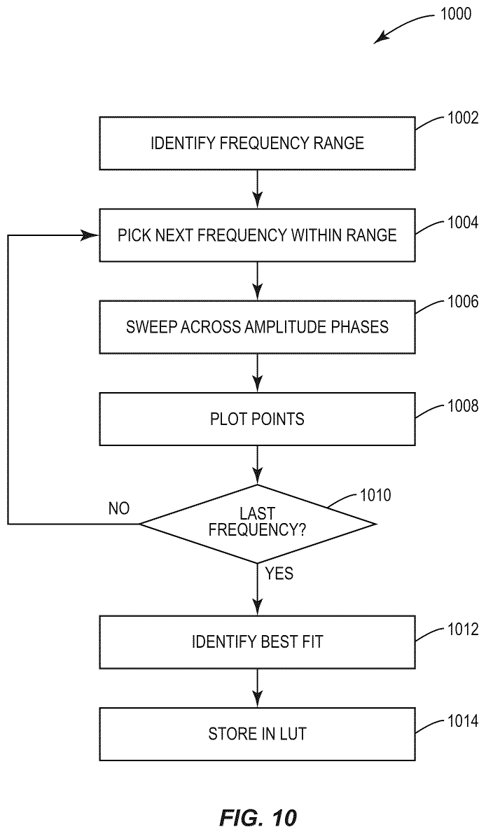

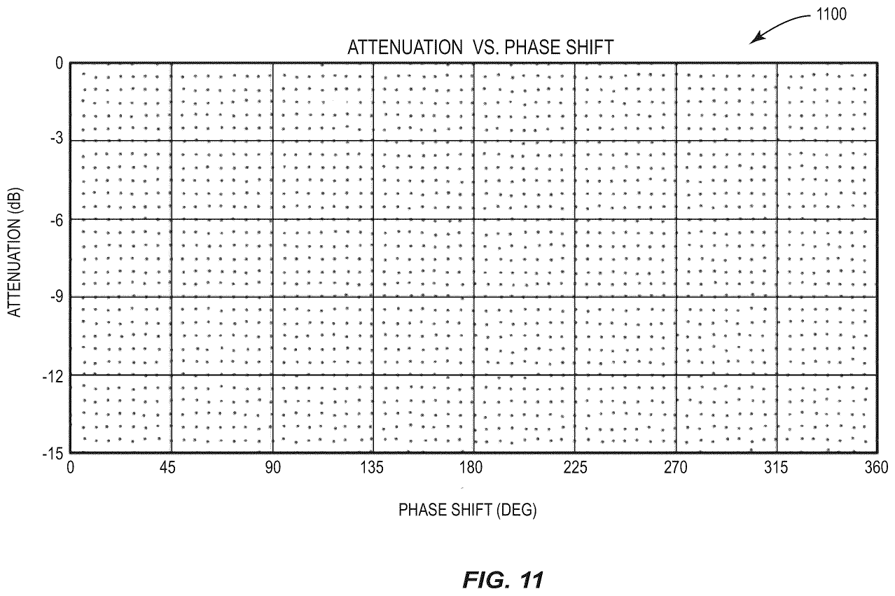

An exemplary process 1000 of selecting the best fit is provided in a flowchart in FIG. 10. Specifically, the process 1000 begins by identifying a frequency range of interest (block 1002). The process picks a next (or first) frequency within the range (block 1004) and tests results by sweeping across amplitude and phase settings for that frequency (block 1006). These results are plotted as points (block 1008) similar to FIG. 6A, 6B, or 8. The process tests whether that is the last frequency in the range. If not, the process 1000 iterates back through until a last frequency is tested. A best fit is identified (block 1012), such as by using a least squares or other statistical fitting method. The resulting point selected is stored in a look up table (LUT) (block 1014) or the like, as shown in FIG. 11.

The points in graph 1100 of FIG. 11 are not precisely regular, indicating that some compromises were made to give a best fit for the various frequencies.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A transceiver comprising:
a phase amplitude controller (PAC) comprising:
a power splitter configured to provide two signals;
a first variable phase shifter coupled to the power splitter and configured to phase shift a first signal of the two signals, wherein the first variable phase shifter is configured to provide a selected phase shift between zero and one hundred eighty degrees;
a second variable phase shifter coupled to the power splitter and configured to phase shift a second signal of the two signals; and
a power combiner coupled to the first variable phase shifter and the second variable phase shifter and configured to combine even modes of the first signal and the second signal while discarding odd modes of the first signal and the second signal such that phase and amplitude are adjusted based on phase shifts provided by the first variable phase shifter and the second variable phase shifter.

2. The transceiver of claim 1, wherein the first variable phase shifter comprises a six-bit phase shifter, wherein bits of the six-bit phase shifter indicate the selected phase shift.

3. The transceiver of claim 1, wherein the first variable phase shifter comprises an eight-bit phase shifter, wherein bits of the eight-bit phase shifter indicate the selected phase shift.

4. The transceiver of claim 1, wherein the first variable phase shifter comprises a switched line circuit.

5. The transceiver of claim 1, wherein the first variable phase shifter comprises a bridge T-type circuit.

6. The transceiver of claim 1, wherein the first variable phase shifter comprises a switched high pass low pass circuit.

7. The transceiver of claim 1, wherein the PAC does not include an attenuator.

8. The transceiver of claim 1, wherein the PAC further comprises a first adjustable attenuator serially positioned between the power splitter and the first variable phase shifter.

9. The transceiver of claim 8, wherein the PAC further comprises a second adjustable attenuator serially positioned between the power splitter and the second variable phase shifter.

10. The transceiver of claim 8, wherein the first adjustable attenuator has no more than three bits of adjustment available.

11. The transceiver of claim 1, wherein the power splitter comprises a Wilkinson power splitter.

12. The transceiver of claim 1, wherein the power combiner comprises a Wilkinson power combiner.

13. An antenna panel configured to be coupled to a tower to provide wireless communication service to user equipment, the antenna panel comprising:
a housing;
a plurality of antenna elements on a front face of the housing; and
a corresponding plurality of transceivers for respective ones of the plurality of antenna elements, wherein each of the corresponding plurality of transceivers comprises:
a phase amplitude controller (PAC) comprising:
a power splitter configured to provide two signals;
a first variable phase shifter coupled to the power splitter and configured to phase shift a first signal of the two signals by a selected phase shift;
a second variable phase shifter coupled to the power splitter and configured to phase shift a second signal of the two signals; and
a power combiner coupled to the first variable phase shifter and the second variable phase shifter and configured to combine even modes of the first signal and the second signal while discarding odd modes of the first signal and the second signal such that phase and amplitude are adjusted based on phase shifts provided by the first variable phase shifter and the second variable phase shifter.

14. The antenna panel of claim 13, wherein respective phase and amplitudes of signals passing through the PACs may be adjusted for beam forming by the antenna panel.

15. The antenna panel of claim 13, wherein the first variable phase shifter comprises a six-bit phase shifter, wherein bits of the six-bit phase shifter indicate the selected phase shift.

16. The antenna panel of claim 13, wherein the PAC further comprises a first adjustable attenuator serially positioned between the power splitter and the first variable phase shifter.

17. The antenna panel of claim 16, wherein the PAC further comprises a second adjustable attenuator serially positioned between the power splitter and the second variable phase shifter.

18. The antenna panel of claim 13, further comprising a look-up table configured to provide settings for elements of the PAC.

19. A method of adjusting phase and amplitude of a signal, comprising:
splitting a signal using a power splitter into a first signal and a second signal;
using a first variable phase shifter to adjust a first phase of the first signal;
using a second variable phase shifter to adjust a second phase of the second signal; and
combining the first signal and the second signal with a power combiner such that even modes of the first signal and the second signal are constructively summed while discarding odd modes of the first signal and the second signal such that phase and amplitude are adjusted based on phase shifts provided by the first variable phase shifter and the second variable phase shifter.

20. The method of claim 19, further comprising attenuating the first signal before adjusting the first phase.
